(19) United States
(12) Patent Application Publication
(10) Pub. No.: US 2023/0047778 A1
(43) Pub. Date: Feb. 16, 2023

(54) STAMPING FOIL USABLE IN ECO-FRIENDLY PAPER PACKING MATERIAL RECYCLABLE THROUGH SEPARATION OF TRANSFER FILM AND PAPER

(71) Applicants: Mi-ae JANG, Seoul (KR); JPNC INC., Pyeongtaek-si, Gyeonggi-do (KR)

(72) Inventor: Mi-ae JANG, Seoul (KR)

(73) Assignees: JPNC INC., Pyeongtaek-si, Gyeonggi-do (KR); Mi-ae JANG, Seoul (KR)

(21) Appl. No.: 17/788,569

(22) PCT Filed: Dec. 24, 2020
(86) PCT No.: PCT/KR2020/019077

§ 371 Date: Jun. 23, 2022

(30) Foreign Application Priority Data
Dec. 24, 2019 (KR) 10-2019-0173582
Jul. 24, 2020 (KR) 10-2020-0092395

(51) Int. Cl. B41M 5/382; B65D 65/40; C09J 7/22; C09J 7/40; C09J 7/38

(52) U.S. Cl. CPC B41M 5/38214; B65D 65/40; C09J 7/22; C09J 7/401; C09J 7/38; B65D 2565/385; C09J 2301/414; C09J 2475/005; C09J 2475/006; C09J 2433/006; C09J 2400/163; C09J 2400/283; C09J 2423/00

(57) ABSTRACT

The purpose of the present invention is to improve surface scratch problems occurring in the manufacturing process and handling of an adherend on which stamping foil is applied, prevent a problem in which a transfer layer of stamping foil is separated at a portion that is bent when the adherend is folded, secure binding force in printing with various inks, and fundamentally prevent powder generated during cutting according to a product standard in a stamping foil manufacturing process. To this end, the stamping foil of the present invention comprises: (a) a base film which is removed after stamping transfer; (b-1) a wear-resistant release layer formed on the base film and containing a polyurethane-based release agent, an acrylic resin, and an ethene-based polymer additive, or (b-2) (i) a polyurethane-based release layer formed on the base film and (ii) a wear-resistant layer formed on the polyurethane-based release layer and containing an acrylic matrix resin and an ethene-based polymer additive; (c) a moisture penetration-preventing and metal-deposited heat-resistant cured coating layer; (d) a metal deposition layer formed on the moisture penetration-preventing cured coating layer; and (e) optionally, a thick film protective layer formed on the metal deposition layer, for preventing the corrosion of the metal deposition layer.

### TECHNICAL FIELD

The present invention relates to a stamping foil usable in an eco-friendly paper packaging material recyclable by separating a transfer film and a paper sheet, and to a method of manufacturing an adherend obtained by applying the stamping foil.

### BACKGROUND ART

Conventional laminated type packaging materials are manufactured by laminating a metal deposition film or a plastic film (such as PET or BOPP film) on a paper sheet. Since it is expensive and inefficient to separate the plastic film and the paper sheet one by one, the packing materials are discarded in a laminated state after use. Furthermore, since it is not allowed to landfill the laminated packaging materials, disposal of the plastic-laminated packaging materials is regulated to incinerate all of them disadvantageously.

Conventional paper packaging materials are manufactured by using a plastic film or depositing metal on a plastic film, applying polysol (or polyvinyl acetate) or various paper adhesives (such as polyurethane) on the plastic film or the metal deposition surface, directly laminating it on a paper sheet, and printing various types of ink (such as PVC ink, acryl ink, PET ink, PP ink, or UV offset ink) on the plastic film surface. In this case, in order to guarantee printability and print fixability, a primer agent mixed with a dye is applied. Therefore, when the conventional paper packaging materials are discarded after use, the plastic film remains on the packaging material to be discarded. In this case, since decomposition of the plastic film in the natural state takes more than hundred years, landfilling is disallowed, and incineration is compulsory inevitably.

Recently, some manufacturers try to obtain the packaging materials by using a biodegradable film instead of the plastic film or depositing a paper sheet on a biodegradable film. However, the biodegradable film deforms over time when used as a packaging material, and thus, it is difficult to guarantee a service life of the packaging material. Therefore, the biodegradable film is not suitable for the packaging material.

The stamping foil is used to transfer a graphic or character pattern containing metal components to an adherend formed of various materials such as a paper product, a plastic-molded product, a leather product, a wood product, and the like. For such a stamping foil, a hot stamping process is used as a type of dry printing method that transfers a pattern by applying heat and pressure using a die of the pattern to be transferred.

The hot stamping process is a type of heat dry printing method in which the stamping foil is placed on a transfer object such as plastic, fiber, leather, or paper, and the stamping foil is pressed with a heated platen to attach a pattern such as characters or figures. Using the hot stamping process, a pattern such as design, color, picture, and text can be printed as a user's desire, and the designed pattern can be printed in the same location regardless of the quantity of the products.

The stamping foil has a stack structure in which a release layer, a color layer, a metal deposition layer, and an adhesive layer are sequentially laminated on a base film formed of polyester resin. The stamping foil is also called “hot stamp tape”, “thermal transfer tape”, or the like.

Recently, there is a high demand in the market for a new type of stamping foil that can print UV ink of various colors on the stamped surface obtained by the stamping process because there is a limitation in applying various colors or designs to the stamping foil and obtaining visual clarity of the design. Accordingly, stamping foils capable of printing various colors of UV ink on the transferred adherend surface have been developed in the art.

The stamping foil may be a laminated type having a release layer on a base film for coating, a coloring layer for exhibiting color by mixing a coloring dye or pigment, a metal deposition layer for exhibiting metallic luster by depositing metal such as aluminum, and a protection layer for providing an adhesive force for the adherend or protecting the deposition layer. Alternatively, the stamping foil may be manufactured by sequentially coating the release layer, the coloring layer (or protection layer), the metal deposition layer (substantially, aluminum layer), and the adhesive layer on the base film, and the components, compositions, or thicknesses of each layer may change depending on the use purpose.

In order to desirably use the stamping foil in the hot stamping process, it is necessary to satisfy several conditions. First, the stamping foil is required to have glossiness and chemical resistance. Second, it is required to have heat resistance to withstand a high-temperature thermo-compression process after the adhesive solution application process. Third, a strong inter-layer adhesion force is required to prevent the coloring layer from being separated from the metal layer during the process of separating the base film and the release layer after transferring the desired pattern onto the transfer object (such as paper, fiber, and leather). In addition, the base film and the release layer are required to have releasability suitable for the use purpose so as to facilitate separation, and the strong solvent resistance is required. Furthermore, the stamping foil is also required to have cuttability to clearly distinguish the pattern of the stamping die.

### DETAILED DESCRIPTION

### Technical Problems

The present invention provides an eco-friendly paper packaging material that can be recycled as a raw material through treatment in a paper recycling facility (i.e., pulper) in which a stamping foil coated with a removable plastic film and then transferred to a paper sheet is removed for disposal of the paper packing material.

In addition, the present invention provides a paper packaging material capable of improving a surface scratch problem that may occur during a manufacturing or handling process for an adherend having a stamping foil and preventing the transfer layer of the stamping foil from being separated at a bent portion during an adherend folding process.

In addition, the present invention provides a paper packaging material capable of guaranteeing print fixability and ink printability in printing on a paper adherend having the transferred stamping foil.

In addition, the present invention provides a paper packaging material manufacturing process capable of fundamentally preventing debris that may occur when the stamping foil is cut for each product standard.

### Technical Solutions

According to a first aspect of the present invention, there is provided a stamping foil comprising: (a) a base film removed after transfer by stamping; (b) any one of (b-1) a wear-resistant release layer formed on the base film, the wear-resistant release layer containing a polyurethane-based release agent, acrylic resin, and an ethene-based polymer additive, or (b-2) (i) a polyurethane-based release layer formed on the base film, and (ii) a wear-resistant layer formed on the polyurethane-based release layer, the wear-resistant layer containing acrylic matrix resin and an ethene-based polymer additive; (c) a moisture blocking and metal deposition heat-resistant cured coating layer; (d) a metal deposition layer formed on the moisture blocking and metal deposition heat-resistant cured coating layer; and (e) optionally, an anti-corrosion thick protection layer formed on the metal deposition layer.

According to a second aspect of the present invention, there is provided a method of manufacturing an adherend by applying the stamping foil according to the first embodiment, the method comprising: first step for (i) applying an adhesive layer on a thick protection layer of the stamping foil or using a stamping foil having an adhesive layer on the thick protection layer, or (ii) applying an adhesive layer on the entire surface of the adherend or on a part of the surface of the adherend; second step for transferring the stamping foil by stamping onto the adherend; third step for removing the base film of the stamping foil; and optionally, fourth step for performing printing on a surface of the release layer exposed by removing the base film.

Now, the present invention will be described.

Using the stamping foil according to the present invention, it is possible to improve a surface scratching problem that may occur in a process of manufacturing or handling an adherend obtained by applying the stamping foil, and to prevent a transfer layer of the stamping foil from being separated from the bent portion in folding. In addition, it is possible to provide print fixability with various types of ink and fundamentally prevent debris that may be generated in cutting of the stamping foil on the basis of a product standard during the manufacturing process.

The stamping foil according to the present invention has:

(a) a base film removed after transfer by stamping;

(b) any one of

(b-1) a wear-resistant release layer formed on the base film, the wear-resistant release layer containing a polyurethane-based release agent, acrylic resin, and an ethene-based polymer additive, or

(b-2) (i) a polyurethane-based release layer formed on the base film, and (ii) a wear-resistant layer formed on the polyurethane-based release layer, the wear-resistant layer containing acrylic matrix resin and an ethene-based polymer additive;

(c) a moisture blocking and metal deposition heat-resistant cured coating layer;

(d) a metal deposition layer formed on the moisture blocking and metal deposition heat-resistant cured coating layer; and

(e) optionally, an anti-corrosion thick protection layer formed on the metal deposition layer.

According to the present invention, the base film to be removed after transfer by stamping may be a plastic film.

The base film includes, for example, a polyethylene terephthalate (PET) film or a biaxially oriented polypropylene (BOPP) film, but not limited thereto. In general, base films formed of other materials are not employed because it is difficult to manufacture the stamping foil in terms of material properties.

The PET material (polyethylene terephthalate) is relatively dense polyester resin, and is a crystalline or amorphous thermoplastic material. Although the amorphous PET has high transparency, it has a weak tensile strength and low slidability. Therefore, it is used for bottles or packaging in general. The crystalline PET has high hardness, high rigidity, high strength, excellent slidability, and wear resistance (compared to POM). Therefore, it is mainly used as a base film in manufacture of the stamping foil.

The BOPP film is a film that contains polypropylene as a main raw material and is biaxially stretched in a machine direction or a vertical direction. The BOPP film has a strong mechanical strength and excellent optical properties because of the biaxial stretching, and is widely used for food packaging or paper laminating purposes.

In the stamping foil, the release layer has a low adhesion with the base film, which is the transfer film. When the stamping foil is transferred onto the adherend, and the base film is removed, the release layer is located in the uppermost layer of the transferred surface. Therefore, it is preferable that the release layer is UV ink printable, and has a good UV ink adhesion. If wax-based resin (such as OP wax or PE wax), cellulose-based resin (such as cellulose acetate or cellulose acetate butyrate), or acrylic resin (such as methyl methacrylate) is used as the release agent, printing is difficult because it has a limitation in the ink printability or ink fixability with various types of ink to be printed (such as PVC ink, acryl ink, PET ink, or PP ink) and UV offset printing.

On the other hand, in the stamping foil (A) according to an embodiment of the present invention, the release layer (b-2) (i) provided on the base film is formed of polyurethane-based resin.

The polyurethane-based resin may contain an element selected from a group consisting of polyurethane, polyether polyurethane, or polycarbonate polyurethane.

The coating solution for forming the release layer may contain polyurethane-based resin and a diluent solvent.

The release layer is coated by using a gravure coating method, in which the mesh of the gravure roll is a 175 mesh, and the diluent solvent used for adjusting the solid content is methyl cellusolve (ethylene glycol monomethyl ether). When the coating is performed as described above, the solid content of the polyurethane-based release composition is within a range of 0.5 to 3 wt %, and preferably 0.8 to 1.5 wt %.

The gravure printing is a type of engraving printing, and is a method of printing by filling ink in the concave part of the printing plate.

The release layer has a different release effect depending on the coating thickness.

The dry coating amount of the polyurethane-based release agent may be 0.1 to 1 g/m2. Within the coating amount range described above, it is possible to easily separate the release layer from the base film and obtain perfect ink printability and ink fixability (especially, for the UV offset ink). If the polyurethane resin is applied with a dry coating amount lower than 0.1 g/m2, a tearing problem may occur when the base film is removed after transfer. If the dry coating amount exceeds 1.0 g/m2, the release layer may be removed too easily during the transfer operation, and the debris may contaminate the adherend of the stamping foil.

For the polyurethane-based release layer, a polyurethane-based release agent having an elongation of 100% or higher may be employed in order to provide excellent printability and perfect print fixability with various types of ink (such as PVC ink, acryl ink, PET ink, or PP ink) and the UV offset ink printing and facilitate the entire surface transfer process.

According to an embodiment of the present invention, a wear-resistant layer containing acrylic matrix resin and an ethene-based polymer additive is applied just below the polyurethane-based release layer exposed by removing the base film of the stamping foil (A). Therefore, it is possible to improve a surface scratching problem that may occur during the adherend manufacturing or handling process to which the stamping foil is applied, and improve a problem that the transfer layer of the stamping foil is separated at the bent edge when the adherend is folded (Example 2).

In the stamping foil (A) according to an embodiment of the present invention, the wear-resistant layer is obtained by using acrylic resin having bondability with the polyurethane-based release layer as matrix resin, and adding ethane-based polymer to solve the problem described above.

In order to maintain the wear resistance and bondability with the polyurethane-based release layer, the coating solution of the wear-resistant layer applied on the polyurethane-based release layer formed on the base film may contain acrylic resin of 16 to 18 wt % and wear-resistant ethene-based polymer of 3 to 5 wt %, and other solvents of 77 to 81 wt %. Therefore, as the acrylic resin content increases over the content described above, the wear resistance may decrease. As the ethene-based polymer content increases over the content described above, the bondability with the polyurethane-based release layer may decrease.

If the wear-resistant layer is applied with a dry coating amount of 0.4 to 2 g/m2, it is possible to prevent scratching on the paper surface and separation at the folded portion when handling the paper packaging material.

In addition, in a stamping foil (B) according to another embodiment of the present invention, a wear-resistant release layer (b-1) having ink fixability is formed by applying polyurethane-based release resin, acrylic matrix resin, and a coating solution containing an ethene-based polymer additive on the base film (Example 6).

The wear-resistant release layer (b-1) of the stamping foil (B) according to another embodiment of the present invention is different from that of the stamping foil (A) according to the embodiment of the present invention. That is, the wear-resistant release layer (b-2) is a combination of the (i) base polyurethane-based release layer formed on the film and the (ii) wear-resistant layer containing acrylic matrix resin and an ethene-based polymer additive, formed on the polyurethane-based release layer.

Using the coating formed of the mixed resin coating solution on the base film, it is possible to easily remove the base film and provide wear resistance against surface scratching. The polyurethane resin, as a release agent, facilitates removal from the base film, and provides perfect ink fixability and printability with various types of ink (especially, UV offset ink). The ethene-based polymer additive provides wear resistance to the surface exposed after transfer of the stamping foil by stamping onto the adherend and removal of the base film. The acrylic resin is used as a matrix resin compatible with both the polyurethane release resin and the ethene-based polymer additive that provides wear resistance. In this case, various other types of resin may be used instead of the acrylic resin. However, the acrylic resin is preferable because transparency is excellent, and the glossiness is improved in subsequent metal deposition.

In addition, the coating film formed of the mixed resin coating solution provides excellent compatibility between the components of the coating solution, so that printing is possible even when the polyurethane-based release resin coating layer is uniformly mixed with the acrylic matrix resin and the ethene-based polymer additive. Furthermore, it is possible to implement a coating surface that is smooth enough to reflect light in a certain direction like a mirror when forming a coating film due to excellent mixability between the components of the coating solution.

In the stamping foil (B) according to another embodiment of the present invention, the wear-resistant release layer may have a dry coating amount of 0.5 to 2 g/m2.

In addition, in order to provide wear resistance simultaneously with releasing when forming the wear-resistant release layer, the wear-resistant release layer may contain a polyurethane release agent of 5 to 30 wt %, acrylic matrix resin of 50 to 80 wt %, an ethene-based polymer additive of 2 to 5 wt %, and other solvents.

It is possible to easily separate the release layer from the base film within the dry coating amount range and the content range described above, and provide perfect ink printability and ink fixability (especially, for the UV offset ink) as well as the wear resistance.

If the dry coating amount is less than 0.5 g/m2, a tearing problem may occur when the base film is removed after transfer. If the dry coating amount is more than 2 g/m2, the release layer may be separated too easily during the transfer operation, and debris may contaminate the adherend of the stamping foil.

Herein, as the polyurethane-based release resin, a polyurethane-based release agent having an elongation of 100% or higher may be employed so that it is possible to provide excellent printability and a perfect print fixability to various types of ink (such as PVC ink, acryl ink, PET ink, and PP ink) and UV offset ink printing and facilitate the entire surface transfer operation.

Herein, the “acrylic resin” is a generic term for thermoplastic synthetic resin formed of polymer of acrylic acid, methacrylic acid, or its derivatives, and its representative example is polymethyl methacrylate.

The acrylic resin may include, for example, polymethyl methacrylate (PMMA), modified polymethyl methacrylate (Modified PMMA), or the like, but not limited thereto.

The PMMA is acrylic resin polymerized by using MMA (methyl methacrylate) monomer as a main raw material.

The PMMA resin is widely used because of its excellent permeability, excellent weather resistance, excellent colorability, and beautiful appearance. In addition, The PMMA is linear polymer and is amorphous, has an excellent surface strength, and exhibits wear resistance, heat resistance, and high rigidity.

As the ethene-based polymer, ethene homopolymer is used in general. It is also called ethylene homopolymer, polyethylene wax, or ethylene resin.

The ethene-based polymer (polyethylene) may include, for example, ethene homopolymer, ethylene acrylic acid copolymer, polydimethyl siloxane, or the like, but not limited thereto.

Using the coating solution containing polyurethane-based release resin, acrylic matrix resin, and ethene-based polymer additives, capable of exhibiting releasability and wear resistance, it is possible to provide various functions of the stamping foil depending on the content of each component.

For example, as the content of the polyurethane release resin increases, separation from the base film becomes easy, and various ink fixability and printability are improved, but wear resistance is degraded. As the content of ethene-based polymer additive increases, the wear resistance improves, but the ink fixability and printability are degraded. As the content of the acrylic matrix resin increases, the glossiness after metal deposition is significantly improved.

According to an embodiment of the present invention, the stamping foil (A) may have a cured coating layer formed on the wear-resistant layer to provide moisture blocking and heat resistance by metal deposition.

According to another embodiment of the present invention, the stamping foil (B) may have a coating layer formed on the wear-resistant release layer to provide moisture blocking and heat resistance by metal deposition.

The cured coating layer may form a coloring layer by mixing a dye for implementing a color with the coating solution. Therefore, the coloring layer is formed in general by applying a mixture of curable resin and a dye to protect the metal deposition layer and provide a color, and it affects durability and weather resistance of the stamping foil.

As a method for preparing the coloring solution employed to form the coloring layer, there are known an isocyanate curing method, a melamine curing method, and a blocked isocyanate curing method.

In the isocyanate curing method, a solution obtained by mixing diallyl phthalate resin, nitro cellulose resin, vinyl chloride vinyl acetate copolymer resin, hydroxy acrylate resin with various solvents at certain ratios is used as a main material. Here, isocyanate is mixed at a certain ratio as a curing agent. Then, the mixed solution is dried at a drying temperature of 185 to 195° C. for 5 to 10 seconds. As a result, it is possible to produce a stamping foil having a post-metal-deposition heat resistance (the highest temperature at which there is no thermal change in the metal deposition layer) reaching up to 180□C.

In the melamine curing method, a solution obtained by mixing melamine resin and maleic resin mixed at a certain ratio as a main material and then mixing diethyl phosphate as a curing catalyst with various solvents at certain ratios is dried at a drying temperature of 185 to 195□C for 5 to 10 seconds. As a result, it is possible to produce a stamping foil having a post-metal-deposition heat resistance (the highest temperature at which there is no thermal change in the metal deposition layer) reaching up to 160□C.

In the blocked isocyanate curing method, a solution obtained by simultaneously mixing diallyl phthalate resin, nitro cellulose resin, vinyl chloride vinyl acetate copolymer resin, blocked Isocyanate resin with various solvents is dried at a drying temperature of 185 to 195□C for 5 to 10 seconds. As a result, it is possible to produce a stamping foil having a post-metal-deposition heat resistance (the highest temperature at which there is no thermal change in the metal deposition layer) reaching up to 150□C.

In the three methods of producing the coloring solution, i.e., the isocyanate curing method, the melamine curing method, and the blocked isocyanate curing method, the heat resistance temperature of the metal deposition layer reaches 180□C, 160□C, and 150□C, respectively. Therefore, it is advantageous to employ the isocyanate curing method.

This means that the paper packaging material obtained by employing the isocyanate curing method has no change even when the storage temperature increases up to 180° C.

Using the coloring solution described above, even after transferring and printing various types of ink, it is possible to block moisture and prevent other contamination from the outside due to the unique cured coating of the coloring layer and provide heat resistance by metal deposition. Therefore, there is no change in the packaging material even when it is used for packaging for a long time.

In addition, in the case of the coloring solution described above, if various types of dyes are added in the production process of the coloring solution, it is possible to exhibit nearly an infinite number of colors.

In the case of the coloring solution described above, the dry coating amount of 5 the coloring solution is preferably set to 1 to 2 g/m2.

Typically, the metal deposition layer of the stamping foil is used to provide glossiness.

Aluminum (Al), nickel (Ni), chromium (Cr), silver (Ag), and copper (Cu) are used in metal deposition in order to provide glossiness in the stamping foil manufacturing process. Most of the cases, aluminum (Al) is vacuum-deposited.

When nickel (Ni) or chromium (Cr) is vacuum-deposited, a titanium color is exhibited. When copper (Cu) is vacuum-deposited, a brass color is exhibited. If a dye is added to the coloring solution before vacuum deposition of aluminum (Al), it is possible to exhibit not only the colors described above but also nearly an infinite number of gloss colors. Therefore, the aluminum (Al) vacuum deposition method is mainly used. When the aluminum vacuum deposition is performed, the thickness of the deposition layer is preferably set to 0.001 to 0.0001 Å, and the OD (optical density) is preferably set to 2.4±0.5.

The stamping foil according to the present invention preferably has a thick protection layer formed on the metal deposition layer. In this case, if the thick protection layer is formed by mixing the stamping foil adhesive and the vinyl-based resin or polyurethane-based adhesive resin having metal bondability with a solvent, it is possible to prevent corrosion of the metal deposition layer and prevent debris from being generated when cutting the product depending on various standards in the stamping foil manufacturing process (see Example 7).

In the case of vacuum deposition of metal, when the deposition layer is exposed to moisture (H₂O) or other contaminants, the deposition layer corrodes over time and becomes deformed, so that the packaging material looks like having fungus or the like. Therefore, various types of vinyl-based resin (such as polyvinyl chloride, vinyl chloride, vinyl acetate copolymer, or polyvinyl acetate) or polyurethane-based adhesive resin having an excellent metal bondability are mixed to various conventional solvent-type adhesives (paper, textile, plastic, etc.) used for the stamping foil, so as to form a thick protection layer having a dry coating amount of 0.2 to 2 g/m2. As a result, it is possible to perfectly block mixing of debris generated at the time of cutting the product on the basis of the standard. Therefore, it is possible to perfectly block the contamination of the adherend during transfer to the paper sheet.

In this case, the thick protection layer may contain a conventional stamping foil adhesive (such as adhesives for paper, fiber, plastic, and the like) of 5 to 30 wt %, vinyl-based resin or polyurethane-based adhesive resin of 10 to 50 wt %, and other solvents.

The stamping foil adhesive may be, for example, a solvent-based adhesive, such as natural rubber-based, synthetic rubber-based, and acrylic-based adhesives, but not limited thereto.

Various other types of polymer resin (especially, polyurethane adhesive resin) may be employed instead of the vinyl-based resin. However, it is advantageous to use the vinyl-based resin because it provides the most excellent bondability with the metal deposition layer.

In addition, the thick protection layer can prevent penetration of the polysol, poly vinyl acetate, and moisture contained in various types of paper adhesives (polyurethane) used for paper adhesion and the paper sheet. Therefore, it is possible to safely use the paper packaging material.

The stamping foil according to the present invention may include an adhesive layer bonded to the adherend, or an adhesive layer may be formed on the adherend instead. An adhesive layer applied by selecting suitable resin depending on the type of adherend to be transferred by stamping may also be provided. Formulation is different depending on the adherend to be transferred.

Any component commonly used in the art may be used without a limitation for elements other than the release layer and the thick protection layer of the present invention.

According to the present invention, there is provided a method of manufacturing an adherend by applying the stamping foil, the method comprising: first step for (i) applying an adhesive layer on a thick protection layer of the stamping foil or using a stamping foil having an adhesive layer on the thick protection layer, or (ii) applying an adhesive layer on the entire surface of the adherend or on a part of the surface of the adherend; second step for transferring the stamping foil by stamping onto the adherend; third step for removing the base film of the stamping foil; and optionally, fourth step for performing printing on a surface of the release layer exposed by removing the base film.

In this case, if the adherend is a paper product or a wooden product, the adherend printed by using the stamping foil of the present invention is recyclable.

For example, if the stamping foil according to the present invention is used for transfer to a paper sheet, polysol or various adhesives are applied to the thick protection layer of the stamping foil, and the stamping foil is laminated with the paper sheet. Then, only the paper sheet remains by removing the plastic film of the stamping foil. This allows an eco-friendly recyclable paper packaging material.

If the adherend is a paper sheet, and the stamping foil is for paper transfer, the packaging product can be recycled as a raw material through treatment in a paper recycling facility (pulper) at the time of disposal of the paper packaging material to which the stamping foil has been transferred, and from which the plastic film has been removed. Therefore, the discarded paper packaging material can be recycled as a raw material by processing it in a paper recycling facility (pulper) provided in a raw material processing process of a paper company. Therefore, it is possible to recycle resources, save energy, and reduce cost.

In the printing of the fourth step, a graphic pattern, text, or both of them can be printed, and color printing is also allowed.

In the printing of the fourth step, PVC ink, acryl ink, PET ink, or PP ink may be used, and UV offset printing is also allowed.

In the “offset printing”, the ink is separated from a printing plate (“off”), and a pattern is transferred to a rubber plate and is then applied to a paper sheet (“set”). The offset printer does not print directly on a paper sheet from the printing plate, but employs an indirect printing method in which a pattern is printed on a rubber plate once, and is then transferred to a paper sheet.

The printing plate used in the offset printing is a flat plate having no unevenness, and special chemical treatment is applied to the surface of the flat plate. ‘Water’ is applied to the printing plate, but this water is applied only to a non-patterned portion having no ink, but not to a patterned portion where ink remains. In general, the offset printer has three devices: a plate drum, a rubber drum, and a pressure drum. The plate surface is placed outside of the drum, and only the printing portion is moved to the rubber drum. The pressure drum is used to press the paper sheet against the printing surface of the rubber drum. In the case of 4-color-process offset printing, the ink is used to express subtle tones by adding black to three primary colors (yellow, red, and blue) and printing these colors overlappingly.

In the UV offset printing, UV-curing ink is becoming inevitable in an effort to reduce organic solvents, which may generate a health problem of an environmental worker by using the solvent type ink. Compared with the conventional inks, the UV curable ink has many advantages such as instant drying, low-temperature and high-speed productivity, bioenergy, solvent-free, pollution-free, and the like.

In the UV offset printing, the ink that can be instantly cured (hardened) when exposed to ultraviolet (UV) light is employed.

In general, the UV curable ink is mainly employed where the printed material such as PP, PVC, or PET does not dry or absorb well. Since there are various types of UV curable ink, they are increasingly used not only in the offset printing but also in the rotary press. The UV curable ink includes, for example, general UV ink, UVpp ink (for unbondable plastics), UV magnetic ink, UV matte ink, UV fluorescent ink, UV clear ink, and the like.

### Advantageous Effects of the Invention

The stamping foil according to an embodiment of the present invention (for example, a film obtained by applying the wear-resistant release layer or a combination of the release layer and the wear-resistant layer, the coloring layer, the metal deposition layer, and the thick protection layer resin to a plastic film) can be used for manufacturing an eco-friendly paper packaging material that can be recycled by releasing the plastic film of which coated surface has been transferred to the paper sheet and utilizing only the paper sheet.

According to another embodiment of the present invention, a mixture of the polyurethane-based release agent, the acrylic matrix resin, and the ethene-based polymer additive is applied to the wear-resistant release layer exposed by removing the base film of the stamping foil. Therefore, it is possible to provide suitable releasability, excellent printability for various types of ink (such as PVC ink, acryl ink, PET ink, and PP ink), and perfect print fixability. In addition, it is possible to prevent a surface scratching problem that may occur in a manufacturing or handling process of the adherend obtained by applying the stamping foil and a problem of separation of the transfer layer of the stamping foil that may occur at bent edge portion when the adherend is folded.

Furthermore, it is possible to recycle the paper packaging material because the plastic film is not attached.

Through the UV offset printing using PVC ink, acryl ink, PET ink, PP ink, UV offset ink, and the like, it is possible to obtain perfect printability and print fixability.

If polyurethane resin having an elongation of 100% or higher is employed, it is possible to facilitate the entire surface transfer operation.

Since the ethene-based polymer additive is mixed with the acrylic matrix resin, it is possible to avoid a surface scratching problem that may occur in the packaging material manufacturing or handling process and prevent a problem of separation of the transfer layer that may occur at the edge when the packaging material is folded.

Since any external influence is blocked by the cured colored coating film, it is possible to prevent penetration of moisture from the outside after transfer to a paper sheet, and thereby guarantee a service life of the packaging material.

It is possible to exhibit various colors by mixing various dyes in the coloring solution.

It is possible to provide high-quality packaging materials having a gloss effect due to the metal deposition layer.

Since corrosion of the metal deposition layer by moisture in the paper sheet as an adherend can be prevented, it is possible to use the paper packaging material for a long time.

In addition, since the thick protection layer obtained by adding vinyl-based resin (or polyurethane adhesive resin) is employed, it is possible to perfectly prevent mixing of debris that may occur when cutting the product on the basis of each standard in the stamping foil manufacturing process. Therefore, it is possible to perfectly block contamination of the adherend in the paper transfer operation.

In addition, it is possible to recycle the plastic films as fibers (polyester) or packaging containers by melting the plastic films (such as the PET film) removed after the paper transfer operation and making chips therefrom. Therefore, it is possible to save resources.

In addition, it is possible to fundamentally prevent carbon dioxide (CO2) that may be generated when the conventional laminated packaging materials are incinerated for refuse disposal. Therefore, it is possible to prevent air pollution and save energy.

### BRIEF DESCRIPTION OF THE DRAWINGS

FIG. 1 is a cross-sectional view illustrating stamping foil products A and B according to an embodiment of the present invention.

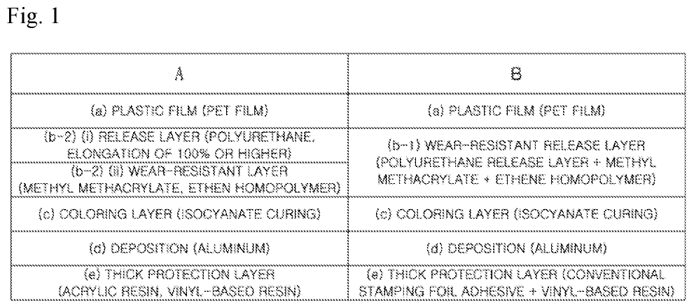

### MODES FOR EMBODYING THE INVENTION

Preferred embodiments of the invention will now be described in details with reference to the accompanying drawings. It is noted that the following exemplary embodiments are merely for clear description, and they may be changed or modified in various different ways without departing from the spirit or scope of the present invention.

### Example 1: Manufacture of Stamping Foil Having Polyurethane-Based Release Layer

To prepare a stamping foil sample, various release agents (such as OP wax, PE wax, cellulose acetate, cellulose acetate butyrate, methyl methacrylate, and polyurethane) were mixed with a solvent, and each mixture was applied to a PET base film. For the polyurethane-based release agent, polyurethane-based resin having an elongation of 100% or higher was employed, and was applied with a dry coating amount of 0.4 g/m².

After the release agent is applied, a coating layer for preventing moisture penetration was formed by using a coating solution mixed with a gold dye as a colorant on the basis of an isocyanate curing method. Then, vacuum deposition was performed with aluminum. To form a thick protection layer, acrylic resin of 5 wt %, vinyl-based resin of 2 wt %, and a solvent of 93 wt % were mixed and applied. After laminating with a paper sheet using polysol, the plastic base film was removed.

On each release layer exposed on the surface after the removal of the base film, printing was performed with UV offset ink.

TABLE 1

| preparation of sample (film was removed | |
|---|---|
| after transferring stamping foil to paper) | UV offset ink print fixability |
| OP wax/coloring/deposition/protection/ | none at all |
| polysol/paper | |
| PE wax/coloring/deposition/protection/ | none at all |
| polysol/paper | |
| cellulose acetate/coloring/deposition/ | none at all |
| protection/polysol/paper | |
| cellulose acetate butyrate/coloring/ | none at all |
| deposition/protection/polysol/paper | |
| methyl methacrylate/coloring/deposition/ | none at all |
| protection/polysol/paper | |
| polyurethane/coloring/deposition/ | good |
| protection/polysol/paper | |

After printing the UV offset ink, the ink fixability was checked with various types of tapes (such as a scratch tape or an OPP packaging tape) on the printed surface. As a result, it was recognized that only the sample using the polyurethane release agent has excellent print fixability with the UV offset ink (see Table 1).

In addition, after printing using various types of ink (such as PVC ink, Acryl ink, PET ink, and PP ink) on the polyurethane release layer, the print fixability was checked in the same way as described above. As a result, it was recognized that all of them have excellent fixability.

### Example 2: Manufacture of Stamping Foil Having Wear-Resistant Layer Under Polyurethane-Based Release Layer

After applying the polyurethane release agent, as a wear-resistant layer, a resin coating solution mixed with polymethyl methacrylate (PMMA) of 17 wt %, ethene homopolymer of 3.5 wt %, and solvent of 79.5 wt % was applied to obtain a dry coating amount of 1.0 g/m². Then, the surface scratch was compared with those of the samples prepared in Example 1 that have no wear-resistant layer.

TABLE 2

| preparation of sample (film was removed | |
|---|---|
| after transferring stamping foil to paper) | surface scratch |
| OP wax/coloring/deposition/protection/ | scratched |
| polysol/paper | |
| PE wax/coloring/deposition/protection/ | scratched |
| polysol/paper | |
| cellulose acetate/coloring/deposition/ | scratched |
| protection/polysol/paper | |
| cellulose acetate butyrate/coloring/ | scratched |
| deposition/protection/polysol/paper | |
| methyl methacrylate/coloring/deposition/ | scratched |
| protection/polysol/paper | |
| polyurethane/coloring/deposition/ | scratched |
| protection/polysol/paper | |
| polyurethane/wear-resistant layer coating/ | not scratched |
| coloring/deposition/protection/polysol/ | |
| paper | |

The surface scratch was evaluated by scratching 2 to 5 times with a nail on the surface release layer after the transfer. In addition, as a result of rubbing 70 times per minute under a load of 500 g using a wear resistance measurement device, it was recognized that there was no scratch on the sample even after rubbing more than 5,000 times.

There was no surface scratch or separation of the transfer layer at the edge in folding only when the wear-resistant layer is applied under the polyurethane-based release layer.

### Example 3: Manufacture of Stamping Foil Having Thick Protection Layer Applied Under Metal Deposition Layer

A polyurethane-based release layer was formed by applying a coating solution containing polyurethane-based resin with an elongation of 100% or higher to the PET base film to obtain a dry coating amount of 0.4 g/m².

As the wear-resistant layer, a resin coating solution mixed with polymethyl methacrylate (PMMA) of 17 wt %, ethene homopolymer of 3.5 wt %, and solvent of 79.5 wt % was applied to obtain a dry coating amount of 1.0 g/m².

Subsequently, a coating solution containing a gold dye of 1.2 wt % as a colorant was applied to obtain a dry coating amount of 1.2 g/m², and an isocyanate curing method was employed to cure the coloring layer at a high drying temperature of 190° C. for about 8 seconds, so that a coloring layer that prevents moisture penetration and has no metal deposition change was obtained.

Then, aluminum was vacuum-deposited to form a metal deposition layer. To form a thick protection layer on the metal deposition layer, a coating solution containing acrylic resin of 5 wt %, vinyl resin of 2 wt %, and a solvent of 93 wt % was applied to obtain a dry coating amount of 0.5 g/m². After laminating with a paper sheet using polysol, the PET base film was removed.

After transferring to the paper sheet, the sheet was left at a humidity of 80% and a temperature of 24° C. for 6 months, and a temperature and humidity test was performed by using a thermo-hygrostat.

The following Table 3 shows that a result of checking whether the paper transfer surface has changed or not.

TABLE 3

| preparation of sample (film was removed | change of packaging |
|---|---|
| after transferring stamping foil to paper) | material surface |
| polyurethane/wear-resistant layer coating/ | black spots appear after 3 |
| coloring/deposition/polysol/paper | months |
| polyurethane/wear-resistant layer coating/ | no change until 6 months |
| coloring/deposition/protection/polysol/ | |
| paper | |

When the thick protection layer was coated, there was no change on the surface of the packaging material even after 6 months.

For the sample subjected to only vacuum deposition and no thick protection layer coating, block spots like fungus started to appear after 3 months.

### Example 4: Setting of Dry Coating Amount of Each Coating Layer

The stamping foil product includes a PET film, a polyurethane release layer, an acrylic wear-resistant layer, an isocyanate coloring layer, an aluminum deposition layer, and a thick protection layer.

4-1. Polyurethane Release Layer

TABLE 4

| polyurethane layer | |
|---|---|
| dry coating amount | result after transfer |
| 0.08 g/m² | partially separated after film removal |
| 1.20 g/m² | some transfer pieces were mixed after |
| | film removal |

It was appropriate that the polyurethane-based release layer is applied with a dry coating amount of 0.1 to 1.0 g/m².

4-2. Acrylic Wear-Resistant Layer

(1) When methyl methacrylate of 17 wt % and ethene homopolymer of 3.5 wt % were mixed:

TABLE 5

| dry coating amount of | | result of transfer layer |
|---|---|---|
| wear-resistant layer | nail scratching result | separation check in folding |
| 0.30 g/m² | partially scratched | no transfer layer separated |
| 2.50 g/m² | no scratch | transfer layer separated |
| | | partially |

It was appropriate that the wear-resistant layer is applied with a dry coating amount of 0.4 to 2 g/m².

(2) Difference between ratios of methyl methacrylate (MA) and ethene homopolymer (EH)

TABLE 6

| weight ratio | dry coating | |
|---|---|---|
| between | amount of wear- | |
| MA and EH | resistant layer | nail scratch result |
| 17:1.5 | 1.0 g/m² | partially scratched |
| 17:4.5 | 1.0 g/m² | partially separated from |
| | | polyurethane release layer |

As the wear-resistant layer, it is appropriate to apply acrylic resin mixed with methyl methacrylate of 17 wt % and ethene homopolymer of 2 to 4 wt % with a dry coating amount of 0.4 to 2.0 g/m².

4-3. Selection of Coloring Layer

TABLE 7

| coloring layer curing method | heat-resistant temperature after deposition |
|---|---|
| isocyanate curing | 180° C. |
| melamine curing | 160° C. |
| blocked isocyanate curing | 150° C. |

It is advantageous to form the coloring layer by applying the isocyanate curing method in terms of the heat resistance temperature after metal deposition.

4-4. Metal Deposition Layer

Aluminum (Al) is advantageous in vacuum deposition because it is inexpensive, and various colors can be implemented.

4-5. Mixing Ratio Between Acrylic Resin and Vinyl Resin in Thick Protection Layer

TABLE 8

| mixing ratio (wt) between | | |
|---|---|---|
| acrylic resin and | dry coating | |
| vinyl-based resin | amount | result |
| 5:1 | 0.5 g/m² | poorer deposition |
| | | bondability |
| 5:4 | 0.5 g/m² | faster moisture penetration |

For the thick protection layer, it was appropriate to apply a dry coating amount of 0.5 g/m² with a weight ratio of 5:2 between the acrylic resin and the vinyl resin.

### Example 5: Method of Manufacturing (Producing) Stamping Foil Standard Product

If a two-color process coater is used to manufacture the stamping foil product, it is possible to simultaneously apply and dry the wear-resistant agent on the same surface after applying and drying the release agent on the plastic film.

For the plastic base film, a PET Film (SF-100, Hwaseung Industries, Co., Ltd.) having a thickness of 16 μm was employed.

First, to apply the release agent, a solution obtained by mixing a polyurethane release agent of 4 wt % and a solvent of 96 wt % was applied with a 210 mesh gravure roll up to a dry coating amount of 0.4 g/m². When the release agent was applied, four sections of a drying furnace, each 2 m in length, were maintained at 100, 100, 110, and 110° C., respectively, and a production speed was set to 120 m/min.

Second, when the wear-resistant agent was applied, a solution obtained by mixing methyl methacrylate of 17 wt %, ethene homopolymer of 3.5 wt %, and a solvent of 79.5 wt % was applied with a 210 mesh gravure roll up to a dry coating amount of 1.0 g/m². When applying the wear-resistant agent, six sections of the drying furnace, each 2 m in length, were maintained at 100, 130, 140, 150, 130, and 100° C., respectively, and the production speed was set to 120 m/min, similar to that of the release agent.

When applying the colorant, the drying furnace was divided to six sections. After preparing a solution by mixing a gold dye of 1.2 wt % with an isocyanate curing type solution, it was applied with a 210 mesh gravure roll up to a dry coating amount of 1.2 g/m². When applying the colorant, six sections of the drying furnace, each 2 m in length, were maintained at 110, 140, 150, 170, 190, and 100° C., respectively, and the production speed was set to 120 m/min.

After forming the coloring layer, aluminum (Al) was vacuum-deposited. In this case, the deposition thickness was maintained at 2.4 with an optical density meter.

When applying the thick protection agent, a drying furnace having six sections was used. A solution containing acrylic resin of 5 wt %, vinyl-based resin of 2 wt %, and a solvent of 93 wt % were prepared, and it was applied with a 210 mesh gravure roll up to a dry coating amount of was 0.5 g/m². In this case, the six sections of the furnace, each 2 m in length, were maintained at 90, 90, 100, 120, and 100° C., respectively, and the production speed was set to 120 m/min.

### Example 6

6-1. Preparation of Sample of Stamping Foil Having Both Releasability and Wear Resistance

First, a coating solution was prepared by mixing a polyurethane release agent of 10 wt %, acrylic resin of 60 wt %, ethene homopolymer of 4 wt %, and a solvent.

The mixed resin coating solution, and as a control group, various release agents (such as OP wax, PE wax, cellulose acetate, cellulose acetate butylate, and methyl methacrylate) were applied to the PET base film.

After the release agent is applied, a moisture penetration prevention coating layer was formed by using a coating solution mixed with a gold dye as a colorant on the basis of the isocyanate curing method. Then, vacuum deposition was performed with aluminum. To form the thick protection layer, a mixture containing a conventional fiber stamping foil adhesive of 8 wt %, vinyl resin of 15 wt %, and a solvent of 77 wt % were mixed and applied up to a dry coating amount of 1.0 g/m². After laminating with a paper sheet using polysol, the plastic base film was removed to prepare each stamping foil sample.

6-2. Comparison of UV Offset Ink Fixability for Each Stamping Foil Sample

The fixability was compared after printing with the UV offset ink on the release layers of each surface of the stamping foil samples exposed after removal of the plastic base film.

TABLE 9

| preparation of sample (film was removed | |
|---|---|
| after transferring stamping foil to paper) | UV offset ink print fixability |
| OP wax/coloring/deposition/protection/ | none at all |
| polysol/paper | |
| PE wax/coloring/deposition/protection/ | none at all |
| polysol/paper | |
| cellulose acetate/coloring/deposition/ | none at all |
| protection/polysol/paper | |
| cellulose acetate butyrate/coloring/ | none at all |
| deposition/protection/polysol/paper | |
| methyl methacrylate/coloring/deposition/ | little |
| protection/polysol/paper | |
| polyurethane resin + acrylic resin + ethene | good |
| polymer/coloring/deposition/protection/ | |
| polysol/paper | |

After printing the UV offset ink, the ink fixability was checked with various tapes (such as a scratch tape or an OPP packaging tape) on the printing surface. As a result, it was recognized that only the sample obtained from this example by using the coating solution containing polyurethane resin, acrylic resin, and ethene-based polymer has excellent print fixability for the UV offset ink (see Table 9).

In addition, printing was performed with various types of ink (such as PVC ink, acryl ink, PET ink, and PP ink) on the sample obtained by using the coating solution containing polyurethane resin, acrylic resin, and ethene-based polymer in this example. Then, the print fixability was checked in the same way as described above. As a result, it was recognized that all of them have excellent fixability.

6-3. Comparison of Wear Resistance Property for Each Stamping Foil Sample

The samples prepared in Example 6-1 were compared regarding whether the surface exposed after removing the plastic base film is scratched or not. The surface scratching was evaluated by scratching 2 to 5 times with a nail.

TABLE 10

| preparation of sample (film was removed | |
|---|---|
| after transferring stamping foil to paper) | surface scratch |
| OP wax/coloring/deposition/protection/ | scratched |
| polysol/paper | |
| PE wax/coloring/deposition/protection/ | scratched |
| polysol/paper | |
| cellulose acetate/coloring/deposition/ | scratched |
| protection/polysol/paper | |
| cellulose acetate butyrate/coloring/ | scratched |
| deposition/protection/polysol/paper | |
| methyl methacrylate/coloring/deposition/ | scratched |
| protection/polysol/paper | |
| polyurethane resin + acrylic resin + ethene | not scratched |
| polymer/coloring/deposition/protection/ | |
| polysol/paper | |

As a result, it was recognized that only the sample obtained by using the coating solution containing polyurethane resin, acrylic resin, and ethene-based polymer has no surface scratch (see Table 10).

In addition, rubbing was performed 70 times per minute at a load of 500 g using a wear resistance meter for the sample obtained by using the coating solution containing polyurethane resin, acrylic resin, and ethene-based polymer. As a result, it was recognized that the sample was not scratched even after rubbing of 5000 times or more.

In the case of the sample obtained by using the coating solution containing polyurethane resin, acrylic resin, and ethene-based polymer, there was almost no separation of the transfer layer at the edge in folding.

In short, it was recognized that the coating film formed from the coating solution containing polyurethane resin, acrylic resin, and ethene-based polymer of this example can provide both releasability and wear resistance to the surface of the stamping foil and excellent ink fixability.

### Example 7

7-1. Preparation of Sample of Stamping Foil Having Thick Protection Layer Mixed with Vinyl Resin

A coating solution obtained by mixing polyurethane release resin of 10 wt %, acrylic resin of 60 wt %, ethene homopolymer of 4 wt %, and a solvent was applied to the PET base film up to a dry coating amount of 1.0 g/m².

After the mixed resin coating solution having wear resistance and releasability is applied, a moisture penetration prevention coating layer was formed by using a coating solution mixed with a gold dye as a colorant on the basis of the isocyanate curing method. Then, vacuum deposition was performed with aluminum.

As a control group, to form a thick protection layer, a conventional fiber adhesive [silica dioxide (SiO₂)+vinyl chloride vinyl acetate copolymer+acryl copolymer+nitro cellulose+solvent] and a paper adhesive [polyester resin+poly vinyl acetate+polyvinyl butyral+phenolic resin+ silicon dioxide (SiO₂)+thickener+solvent] were applied up to a dry coating amount of 1.0 g/m².

In order to form the thick protection layer of this example, a coating solution obtained by mixing a fiber stamping foil adhesive of 8 wt %, vinyl resin of 15 wt %, and a solvent of 77 wt % was applied up to a dry coating amount of 1.0 g/m².

Then, after laminating with a paper sheet using polysol, the plastic base film was removed to prepare each stamping foil sample.

7-2. Checking on Debris Generated in Thick Protection Layer Mixed with Vinyl Resin

The prepared stamping foil samples were put into a cutter (slitter) to check whether debris is generated at the cut portion or not.

TABLE 11

| preparation of sample (film was removed | |
|---|---|
| after transferring stamping foil to paper) | existence of debris |
| polyurethane resin + acrylic resin + ethene | debris generated |
| polymer/coloring/deposition/ | |
| conventional fiber adhesive/polysol/ | |
| paper | |
| polyurethane resin + acrylic resin + ethene | debris generated |
| polymer/coloring/deposition/ | |
| conventional paper adhesive/polysol/ | |
| paper | |
| polyurethane resin + acrylic resin + ethene | no debris generated |
| polymer/coloring/deposition/fiber | |
| adhesive + vinyl resin/polysol/paper | |

As shown in Table 11, only the sample having the thick protection layer formed by mixing vinyl resin with a conventional fiber adhesive of this example did not generate any debris.

7-3. Comparison of Moisture Blocking Effect of Thick Protection Layer Mixed with Vinyl Resin

How effectively moisture can be blocked was compared between a packaging material sample (control group) obtained by performing vacuum deposition of aluminum and transferring it to a paper sheet without the thick protection layer and a packaging material sample of this example obtained by forming a thick protection layer mixed with vinyl resin and transferring it to a paper sheet.

TABLE 12

| preparation of sample (film was removed | change of packaging |
|---|---|
| after transferring stamping foil to paper) | material surface |
| polyurethane resin + acrylic resin + ethene | black spots appear after 3 |
| polymer/coloring/deposition/polysol/ | months |
| paper | |
| polyurethane resin + acrylic resin + ethene | no change until 6 months |
| polymer/coloring/deposition/protection | |
| layer mixed with vinyl resin/polysol/ | |
| paper | |

For the packaging material sample obtained by performing only vacuum deposition without the thick protection layer, black spots like fungus started to appear after 3 months. On the other hand, for the sample of this example obtained by applying the thick protection layer mixed with vinyl resin, there was no change on the surface of the paper packaging material even after 6 months at a humidity of 80% and a temperature of 24° C.

### Example 8: Setting of Resin Content and Dry Coating Amount for Each Coating Layer

Reflecting the results of Examples 6 and 7, in order to set the resin content and dry coating amount of each coating layer, the stamping foil product composition was selected to include a PET film, a wear-resistant release layer (polyurethane-based release resin, acrylic matrix resin, and ethene-based polymer additive), an isocyanate-cured coloring layer, an aluminum deposition layer, and a thick protection layer containing vinyl resin.

8-1. Setting of ratio of mixed resin (including polyurethane-based release resin, acrylic matrix resin, and ethene-based polymer additive) in wear-resistant release layer

TABLE 13

| resin type | ratio | | result |
|---|---|---|---|
| ethene-based homopolymer | 2 | wt % | surface scratched |
| ethene-based homopolymer | 5 | wt % | lack of offset ink fixability |
| polyurethane release agent | 5 | wt % | bad releasability |
| polyurethane release agent | 30 | wt % | cutting debris generated |
| acrylic resin | 50 | wt % | lack of glossiness |
| acrylic resin | 80 | wt % | lack of offset ink fixability |

For the release and wear-resistant layers, it was appropriate to mix a polyurethane-based release agent of 10 wt %, acrylic resin of 60 wt %, ethene-based polymer of 4 wt %, and other solvents.

8-2. Setting of Dry Coating Amount of Wear-Resistant Release Layer

TABLE 14

| dry coating amount of wear- | |
|---|---|
| resistant release layer | result after transfer |
| 0.50 g/m² | partially separated after film removal |
| 2.0 g/m² | some transfer pieces were mixed after |
| | film removal |

For the wear-resistant release layer, it was appropriate to apply a coating solution obtained by mixing a polyurethane-based release agent of 10 wt %, acrylic resin of 60 wt %, ethene-based polymer of 4 wt %, and other solvents up to a dry coating amount of 1.0 g/m².

8-3. Selection of Coloring Layer

TABLE 15

| coloring layer curing method | heat-resistant temperature after deposition |
|---|---|
| isocyanate curing | 180° C. |
| melamine curing | 160° C. |
| blocked isocyanate curing | 150° C. |

It is advantageous to form the coloring layer by applying the isocyanate curing method in terms of the heat resistance temperature after metal deposition.

8-4. Metal Deposition Layer

Aluminum (Al) is advantageous in vacuum deposition because it is inexpensive, and various colors can be implemented.

8-5. Mixing ratio between fiber adhesive and vinyl-based resin in the thick protection layer

TABLE 16

| mixing ratio (wt) between | | |
|---|---|---|
| fiber adhesive and | dry coating | |
| vinyl-based resin | amount | result |
| 5:50 | 1.0 g/m² | blocking |
| 30:10 | 1.0 g/m² | debris generated |

To form the thick protection layer, it was appropriate to apply a coating solution obtained by mixing a conventional fiber stamping foil adhesive of 8 wt %, vinyl resin of 15 wt %, and a solvent of 77 wt % up to a dry coating amount of 1.0 g/m².

### Example 9: Method of Manufacturing Stamping Foil Standard Product

If a two-color process coater is used to manufacture the stamping foil product, it is possible to simultaneously apply and dry the colorant on the same surface after applying and drying the wear-resistant agent on the plastic film.

For the plastic base film, a PET Film (SF-100, Hwaseung Industries, Co., Ltd.) having a thickness of 16 μm was employed.

First, to form the wear-resistant release layer, a coating solution obtained by mixing a polyurethane-based release agent of 10 wt %, acrylic resin of 60 wt %, ethene homopolymer of 4 wt %, and other solvents of 26 wt % was applied with a 210 mesh gravure roll up to a dry coating amount of 1.0 g/m². For releasing and applying the wear-resistant agent, four sections of the drying furnace, each 2 m in length, were maintained at 100, 100, 110, and 110° C., respectively, and the production speed was set to 120 m/min.

When applying the colorant, the drying furnace was divided to six sections. After preparing a solution by mixing a gold dye of 1.2 wt % with an isocyanate curing type solution, it was applied with a 210 mesh gravure roll up to a dry coating amount of 1.2 g/m². When applying the colorant, six sections of the drying furnace, each 2 m in length, were maintained at 110, 140, 150, 170, 190, and 100° C., respectively, and the production speed was set to 120 m/min, similar to that of the wear-resistant release layer.

After forming the coloring layer, aluminum (Al) was vacuum-deposited. In this case, the deposition thickness was maintained at 2.4 with an optical density meter.

When applying the thick protection agent, a drying furnace having six sections was used. A solution were prepared by mixing a conventional stamping foil adhesive of 8 wt %, vinyl-based resin of 15 wt %, and a solvent of 77 wt %, and it was applied with a 210 mesh gravure roll up to a dry coating amount of was 1.0 g/m². In this case, for the thick protection agent, the six sections of the furnace, each 2 m in length, were maintained at 90, 90, 100, 120, and 100° C., respectively, and the production speed was set to 120 m/min.

1. A stamping foil comprising:
(a) a base film removed after transfer by stamping;
(b) any one of
(b-1) a wear-resistant release layer formed on the base film, the wear-resistant release layer containing a polyurethane-based release agent, acrylic resin, and an ethene-based polymer additive, or
(b-2) (i) a polyurethane-based release layer formed on the base film, and (ii) a wear-resistant layer formed on the polyurethane-based release layer, the wear-resistant layer containing acrylic matrix resin and an ethene-based polymer additive;
(c) a moisture blocking and metal deposition heat-resistant cured coating layer;
(d) a metal deposition layer formed on the moisture blocking and metal deposition heat-resistant cured coating layer; and
(e) optionally, an anti-corrosion thick protection layer formed on the metal deposition layer.

2. The stamping foil according to claim 1, wherein the (b-1) wear-resistant release layer or (b-2) (ii) wear-resistant layer has a dry coating amount of 0.4 to 2 g/m2.

3. The stamping foil according to claim 1, wherein the (b-1) wear-resistant release layer is formed by applying a coating solution containing a polyurethane-based release agent of 5 to 30 wt %, acrylic resin of 50 to 80 wt %, an ethene-based polymer additive of 2 to 5 wt %, and a solvent of the remaining weight percentage, and
the (b-2)(ii) wear-resistant layer is formed by applying a coating solution containing acrylic resin of 16 to 18 wt %, ethene-based polymer additive of 3 to 5 wt %, and a solvent of the remaining amount.

4. The stamping foil according to claim 1, wherein the anti-corrosion thick protection layer is formed by mixing a stamping foil adhesive of 5 to 30 wt %, metal-bondable vinyl-based resin or polyurethane-based adhesive resin having of 10 to 50 wt %, and a solvent and applying the mixture with a dry coating amount of 0.2 to 2 g/m2.

5. The stamping foil according to claim 1, wherein printing is possible on a surface of the release layer exposed after transferring the stamping foil onto the adherend and removing the base film.

6. The stamping foil according to claim 1, wherein the wear-resistant release layer (b-1) exposed after transferring the stamping foil onto the adherend and removing the base film is formed by applying a coating solution obtained by mixing polyurethane-based resin having printability, entire surface transferability, and an elongation of 100% or higher with acrylic resin and ethene-based polymer additive, or
the release layer (b-2) (i) exposed after transferring the stamping foil on the adherend and removing the base film is formed by applying polyurethane-based resin having printability, entire surface transferability, and an elongation of 100% or higher.

7. The stamping foil according to claim 1, wherein the base film to be removed after the transfer by stamping is a polyethylene terephthalate (PET) film or a biaxially-oriented polypropylene (BOPP) film.

8. The stamping foil according to claim 1, wherein the moisture blocking and metal deposition heat-resistant cured coating layer is mixed with a dye for implementing a color in the coating solution to form a coloring layer.

9. The stamping foil according to claim 1, wherein the metal deposition layer is formed by vacuum-depositing metal selected from a group consisting of aluminum (Al), nickel (Ni), chromium (Cr), silver (Ag), or copper (Cu).

10. The stamping foil according to claim 1, wherein the stamping foil is a paper transfer stamping foil.

11. A method of manufacturing an adherend by applying the stamping foil according to claim 1, the method comprising:
first step for (i) applying an adhesive layer on a thick protection layer of the stamping foil or using a stamping foil having an adhesive layer on the thick protection layer, or (ii) applying an adhesive layer on the entire surface of the adherend or on a part of the surface of the adherend;
second step for transferring the stamping foil by stamping onto the adherend;
third step for removing the base film of the stamping foil; and
optionally, fourth step for performing printing on a surface of the release layer exposed by removing the base film.

12. The method according to claim 11, wherein the adherend is a paper sheet, the stamping foil is for paper transfer, and the adherend is recyclable as a raw material through paper recycling facility treatment at the time of disposal of a paper packaging material to which the stamping foil has been transferred, and the plastic film has been removed.

13. The method according to claim 11, wherein the adherend is a paper product or a wooden product, and the adherend printed by the stamping foil is recyclable.

14. The method according to claim 11, wherein the printing of the fourth step is performed by using PVC ink, acryl ink, PET ink, PP ink, or UV offset ink.
